(19) United States
(12) Patent Application Publication
(10) Pub. No.: US 2025/0269335 A1
(43) Pub. Date: Aug. 28, 2025

(54) Gas Injected Chemistry for Single Wafer Processing

(71) Applicant: IMEC VZW, Leuven (BE)

(72) Inventors: Mateusz GOCYLA, Haasrode (BE); Rachid CHOKRI, Deurne (BE); Tibo VANDEVENNE, Leuven (BE)

(21) Appl. No.: 18/655,789

(22) Filed: May 6, 2024

Related U.S. Application Data
(60) Provisional application No. 63/557,308, filed on Feb. 23, 2024.

(51) Int. Cl. B01F 23/20; B01F 23/237; B01F 23/80; B01F 25/53; B01F 35/221; B01F 101/24; B01F 101/58; C09K 13/08; C11D 7/08; H01L 21/67

(52) U.S. Cl. CPC B01F 23/29; B01F 23/237613; B01F 23/803; B01F 25/53; B01F 35/2211; C09K 13/08; C11D 7/08; H01L 21/6704; B01F 2101/24; B01F 2101/58

(57) ABSTRACT

The present disclosure relates to systems and methods for gas injected chemistry for single wafer processing. An example method includes generating, by a gas generator, a gas. The method also includes mixing, in a mixing tank, a gas-enriched chemical mixture comprising the gas and a chemical mixture. The method also includes dispensing, via a sample chamber, a dispensed volume of the gas-enriched chemical mixture onto the substrate. The method also includes returning a spent volume of the gas-enriched chemical mixture to the mixing tank.

### CROSS-REFERENCE TO RELATED APPLICATIONS

The present application is a non-provisional patent application claiming priority to Provisional Patent Application No. 63/557,308, filed Feb. 23, 2024, the contents of which are hereby incorporated by reference.

### BACKGROUND

Unless otherwise indicated herein, the materials described in this section are not prior art to the claims in this application and are not admitted to be prior art by inclusion in this section.

Cleaning of semiconductor wafers is an essential part of the manufacturing of integrated circuits and other computer chips. However, existing methods are often inefficient and time-consuming.

For example, one existing method for cleaning is single-wafer spin cleaning with repetitive use of ozonated water and diluted hydrofluoric acid (HF), or SCROD. In this method, ozonated water and diluted HF are dispensed separately onto a spinning wafer in order to remove metallic contamination. This may be accomplished through two steps: oxidation (via the ozonated water) and etching (via the diluted HF). These two steps may be repeated until the cleaning process is completed. Due to this sequential and repetitive process, the processing of a single 200-300 mm wafer takes around four minutes.

### SUMMARY

The specification and drawings disclose embodiments that relate to gas injected chemistry systems for single wafer processing.

In a first aspect, the disclosure describes a system. The system includes a gas generator configured to generate a gas. The system also includes a mixing tank configured to contain a gas-enriched chemical mixture. The mixing tank may be connected to the gas generator by a gas supply line. The system also includes a sample chamber configured to contain a substrate. The sample chamber may be connected to the mixing tank via a mixture dispense line. The mixture dispense line may be configured to supply a dispensed volume of gas-enriched chemical mixture to the sample chamber. The sample chamber may be connected to a mixing tank via a mixture reclaim line. The mixture reclaim line may be configured to return a spent volume of the gas-enriched chemical mixture to the mixing tank after interaction with the substrate. The system also includes a gas sensor. The system also includes a controller. The controller may be operably connected to the gas generator, the gas sensor, and the sample chamber. The controller may be configured out to carry out program instructions stored in a memory so as to perform operations. The operations include receiving, from the gas sensor, information indicative of a concentration of the gas within the gas-enriched chemical mixture. The operations also include in response to receiving the information, controllably adjusting at least one operational aspect of the system so as to obtain a desired concentration of gas within the gas-enriched chemical mixture.

In a second aspect, the disclosure describes a method. The method includes generating, by a gas generator, a gas. The method also includes mixing, in a mixing tank, a gas-enriched chemical mixture comprising the gas and a chemical mixture. The method also includes dispensing, via a sample chamber, a dispensed volume of the gas-enriched chemical mixture onto the substrate. The method also includes returning a spent volume of the gas-enriched chemical mixture to the mixing tank.

In a third aspect, the disclosure describes a non-transitory computer-readable medium. The non-transitory computer-readable medium include program instructions, that when executed by a processor cause a controller to perform operations. The operations include receiving, from the gas sensor, information indicative of a concentration of the gas within the gas-enriched chemical mixture. The operations also include in response to receiving the information, controllably adjusting at least one operational aspect of the system so as to obtain a desired concentration of gas within the gas-enriched chemical mixture.

The foregoing summary is illustrative only and is not intended to be in any way limiting. In addition to the illustrative aspects, embodiments, and features described above, further aspects, embodiments, and features will become apparent by reference to the figures and the following detailed description.

### BRIEF DESCRIPTION OF THE FIGURES

FIG. 1 is an overview of a gas-injected chemistry system, according to example embodiments.

FIG. 2 is an illustration of a specific example configuration of a gas-injected chemistry system.

FIG. 3 is an illustration of a specific example configuration of a gas-injected chemistry system.

FIG. 4 is an illustration of a specific example configuration of a gas-injected chemistry system.

FIG. 5 is an illustration of a relationship between operational modes of an example configuration of a gas-injected chemistry system.

FIG. 6 is an illustration of an example method.

### DETAILED DESCRIPTION

Example methods and systems are described herein. Any example embodiment or feature described herein is not necessarily to be construed as preferred or advantageous over other embodiments or features. The example embodiments described herein are not meant to be limiting. It will be readily understood that certain aspects of the disclosed systems and methods can be arranged and combined in a wide variety of different configurations, all of which are contemplated herein.

Furthermore, the particular arrangements shown in the figures should not be viewed as limiting. It should be understood that other embodiments might include more or less of each element shown in a given figure. In addition, some of the illustrated elements may be combined or omitted. Similarly, an example embodiment may include elements that are not illustrated in the figures.

### I. Overview

Example embodiments relate to a gas injected chemistry systems for single wafer processing.

As stated previously, existing methods for cleaning of semiconductor wafers are generally inefficient and time-consuming, with the processing of one 200-300 mm wafer with the SCROD method taking around four minutes.

The embodiments described herein overcome these and other technical issues by introducing systems and methods for cleaning semiconductor wafers using a gas-enriched chemical mixture. Using the example of ozonated water and diluted HF, the embodiments herein dispense ozonated HF in a single step, as opposed to current methods of dispensing ozonated water and diluted HF separately. The systems and methods described herein reduce the amount of time to process a single 200-300 mm wafer from four minutes to fifty seconds.

As noted above, an application of this method may be to clean metallic contamination from semiconductor wafers as part of the process of semiconductor manufacturing. In other embodiments, however, the system may be configured to etch one or more materials using an acid or other chemical, such as in an anisotropic or isotropic chemical etch process.

### II. Example Systems

The following description and accompanying drawings will elucidate features of various example embodiments. The embodiments provided are by way of example, and are not intended to be limiting. As such, the dimensions of the drawings are not necessarily to scale.

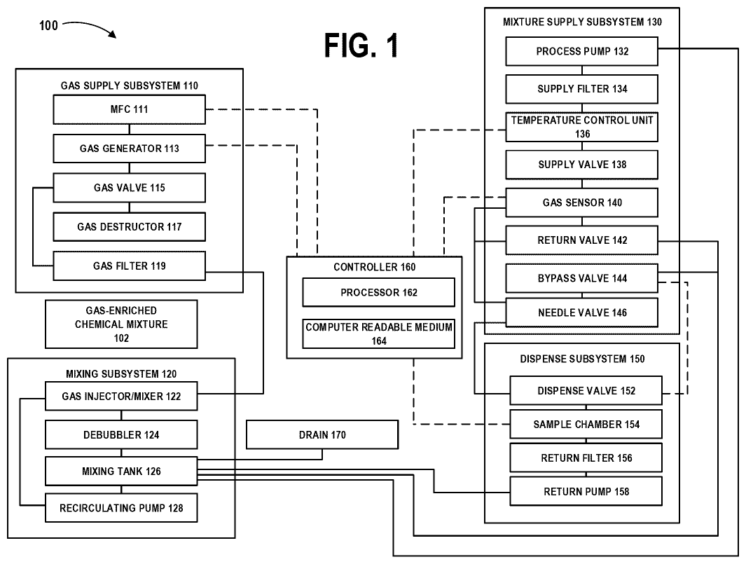

FIG. 1 illustrates an overview of a gas-injected chemistry system 100, according to example embodiments. As described herein the gas-injected chemistry system 100 could be configured to deliver a gas-enriched chemical mixture 102 to a substrate. Connections between elements with a solid line represent pipes or tubes configured for the transport of fluids such as gases and/or liquids. Connections between elements with a dashed line represent an operable connection, such as an electrical, optical, or mechanical connection. It will be understood that the gas-injected chemistry system 100 could include more or fewer connections between respective elements. Additionally or alternatively, the gas-injected chemistry system 100 could include differently-connected elements within the context of the present disclosure.

In various example embodiments, the gas-injected chemistry system 100 may include several subsystems, including (but not limited to) a gas supply subsystem 110, a mixing subsystem 120, a mixture supply subsystem 130, and a dispense subsystem 150.

In some embodiments, the gas-injected chemistry system 100 may also include a controller 160, that, when operably connected to other components of the system, may direct the actions or operational parameters of the other components. The controller 160 may comprise a processor 162 and a computer-readable medium 164.

In some embodiments, the gas supply subsystem 110 may be configured to deliver or move gases to where they are needed, in the required quantities and at the appropriate pressure and purity levels. As an example, the gas supply subsystem 110 may include, but is not limited to, a mass flow controller (MFC) 111, a gas generator 113, a gas valve 115, a gas destructor 117, and a gas filter 119. In some embodiments, the MFC 111 could be configured to measure and control a mass flow rate of a gas moving through the gas-injected chemistry system 100. The MFC 111 and gas generator 113 may be operably connected to the controller 160. In some embodiments, the gas supply subsystem may be referred to as a gas supply line.

The mixing subsystem 120 may include, but is not limited to, a gas injector/mixer 122, a debubbler unit 124, a mixing tank 126, and a recirculating pump 128. The mixing tank 126 may also be connected to a drain 170. In some embodiments, the gas injector/mixer 122 may be referred to as a gas injector.

The mixture supply subsystem 130 may include, but is not limited to, a process pump 132, a supply filter 134, a temperature control unit 136, a supply valve 138, a gas sensor 140, a return valve 142, a bypass valve 144, and a needle valve 146. The temperature control unit 136 and gas sensor 140 may be operably connected to the controller 160. In some embodiments, the mixture supply subsystem may be referred to as a mixture supply line.

The dispense subsystem 150 may include, but is not limited to, a dispense valve 152, a sample chamber 154, a return filter 156, and a return pump 158. The bypass valve 144 may be operably connected to the dispense valve 152, and the sample chamber 154 may be operably connected to the controller 160.

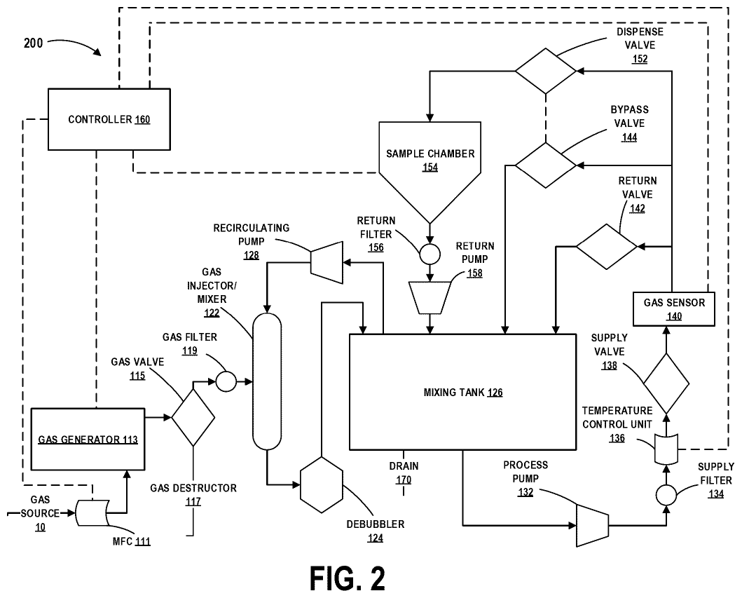

FIG. 2 illustrates an example configuration 200 of the gas-injected chemistry system 100. Connections between elements with a solid line represent pipes or tubes configured for the transport of fluids such as gases and/or liquids. The arrow on such a connection represents the intended direction of the fluid flow. Connections between elements with a dashed line represent an operable connection, such as an electrical, optical, or mechanical connection.

FIG. 2 illustrates a configuration of a gas supply line, which may contain, among other components, the components included in the gas supply subsystem 110 and mixing subsystem 120 as illustrated in FIG. 1.

As illustrated, a gas source 10 may provide a preliminary gas to the gas generator 113. The flow of the preliminary gas from the gas source 10 to the gas generator may be regulated or controlled by a mass flow controller 111. The controller 160 may adjust the operational parameters (e.g. flow control) of the mass flow controller 111 via an operable connection.

In some embodiments, the mass flow controller 111 may regulate the flow of gas to be within the range of 0-2 standard liters per minute (slm), for example in a wafer cleaning application. In other embodiments, the mass flow controller 111 may regulate the flow of gas to be within the range of 0-10 slm, for example in an etching application. In some embodiments, the mass flow controller 111 may be positioned as to be less than 1 meter from the gas generator 113.

In some embodiments, the preliminary gas provided by the gas source 10 may be oxygen (O₂). Other gases are contemplated in for use in other embodiments.

The gas generator 113 may use the preliminary gas to produce a gas for injection. For example, if the preliminary gas is oxygen (O₂), the gas generator may produce ozone (O₃). The controller 160 may adjust the operational parameters (e.g. power control) of the gas generator 113 via an operable connection.

In some embodiments, the gas generator 113 may be configured to produce ozone by breaking down O₂ molecules into individual oxygen atoms, which then combine with other oxygen molecules to form ozone. In such scenarios, the gas generator 113 could operate via coronal discharge, ultraviolet light, and/or electrolysis. Other ways to generate ozone are possible and contemplated within the scope of the present disclosure. In some embodiments, the gas generator 113 may be configured to produce gas concentrations of 0-10 parts per million (ppm).

The gas generator 113 may provide a gas to a gas valve 115. In some embodiments, the gas may be ozone gas and/or an ozone gas mixture. In turn, the gas valve 115 may allow the gas to flow either to a gas injector/mixer 122, or to a gas destructor 117, depending on the configuration of the valve. For instance, if excess gas beyond which is required for the operation of the system is generated by the gas generator 113, the gas valve may be configured or set to provide such excess gas to the gas destructor 117 for destruction, containment, or release.

Gas provided from the gas valve 115 to the gas injector/mixer 122 may be passed through a gas filter 119. The gas filter 119 may be configured to may be configured to filter out debris or other impurities within the gas-enriched chemical mixture 102 that may have been introduced while within the gas injector/mixer 122.

The gas injector/mixer 122 may be configured to inject the gas into a liquid chemical mixture, and further mix the produced gas-enriched chemical mixture such as to better combine the fluids. The gas injector/mixer 122 may be configured to be greater than 30 centimeters (cm) in length. In some embodiments, the gas injector/mixer 122 may be positioned as to be less than one meter from the gas generator 113.

The gas-enriched chemical mixture may be provided to a debubbler unit 124, which may involve passing the mixture through a fine-mesh membrane such that the size and quantity of gas bubbles within the gas-enriched chemical mixture are reduced, eliminated, or otherwise separated from the liquid components of the gas-enriched chemical mixture 102. The debubbler unit may be configured to be between 20 and 50 cm in length. In some embodiments, the debubbler unit 124 may be configured as to be higher up in space than the mixing tank 126.

The gas-enriched chemical mixture 102 may be provided to a mixing tank 126 for storage and further mixing for combination purposes. From the mixing tank 126, the gas-enriched chemical mixture 102 may be returned to the gas injector/mixer 122 via a recirculating pump 128 to ensure the desired concentration of gas within the mixture. The debubbler unit 124, the recirculating pump 128 and the connections between the gas injector/mixer 122, the debubbler unit 124, the mixing tank 126, and the recirculating pump 128 may be referred to in some embodiments as an injection line. The mixing tank 126 may also be connected to a drain 170.

The gas-enriched chemical mixture 102 may be provided to a sample chamber for use in the cleansing of semiconductor wafers, or for other purposes. This is illustrated in FIG. 2 with a configuration of a mixture dispense line, which may contain, among other components, the components included in the mixture supply subsystem 130 and dispense subsystem 150 as illustrated in FIG. 1.

The gas-enriched chemical mixture 102 may be pumped from the mixing tank 126 via a process pump 132. While being pumped, the gas-enriched chemical mixture 102 may be passed through a supply filter 134. The supply filter 134 may be configured to filter out debris or other impurities within the gas-enriched chemical mixture 102 that may have been introduced while within the mixing tank 126.

The gas-enriched chemical mixture 102 may pass through a temperature control unit 136, which may be configured to measure the temperature of the gas-enriched chemical mixture, determine whether the measured temperature is within a specified range, and accordingly heat or cool the gas-enriched chemical mixture if necessary. Such temperature information (e.g. mixture temperature feedback) may be communicated to the controller 160 via an operable connection as described above. In some embodiments, the temperature control unit 136 may include a heat exchange system.

A supply valve 138 may be present in the mixture supply subsystem 130 to control the flow of the gas-enriched chemical mixture 102. For example, the supply valve 138 could be shut to cut off the flow of the gas-enriched chemical mixture 102 in case of emergency.

At one or more locations within the gas-injected chemistry system 100, the gas-enriched chemical mixture 102 may be analyzed by a gas sensor 140, which may be configured to determine the concentration of the gas within the gas-enriched chemical mixture. Such information (e.g. gas concentration feedback) may be communicated to the controller 160 via an operable connection as described above. The gas sensor 140 may be configured to be resistant to corrosion caused by the gas-enriched chemical mixture 102. The gas sensor 140 may also be configured to detect entire possible range of the concentration of gas within the gas-enriched chemical mixture 102. In some embodiments, the gas sensor 140 may be positioned as to be approximately halfway between the mixing tank 126 and the sample chamber 154.

The mixture supply subsystem 130 may include a return valve 142, which under normal operating conditions would usually be closed. If open, the return valve 142 would allow flow from the mixture supply line directly back to the mixing tank 126. For instance, this valve could be used in the case of an emergency to drain the mixture supply line back to the mixing tank 126.

The mixture supply subsystem 130 may also include a dispense valve 152, which controls the flow of the gas-enriched chemical mixture 102 to a sample chamber 154.

The mixture supply subsystem 130 may include a bypass valve 144, which further allows flow from the mixture supply line directly back to the mixing tank 126. The bypass valve 144 may be operably connected to a dispense valve 152 such that if the bypass valve 144 is open, the dispense valve 152 is closed, and vice versa.

Such an arrangement ensures that when the dispense valve 152 is closed and the gas-enriched chemical mixture is not needed in the sample chamber 154, the gas-enriched chemical mixture continues to circulate from the mixture supply line to the mixing tank and back. This constant flow reduces unintended results, such as the fluids changing properties (e.g. gas concentrations and/or temperatures) and helps ensure a consistent and stable mixture.

The sample chamber 154 is configured to dispense a predetermined amount of gas-enriched chemical mixture onto a substrate within the sample chamber 154. In some embodiments, the sample chamber 154 may be positioned such that the distance between the mixing tank 126 and the sample chamber 154 is less than 10 meters.

The sample chamber 154 may be configured to dispense the predetermined amount of gas-enriched chemical mixture onto a substrate by spraying, by immersing the substrate in a bath of the gas-enriched chemical mixture, or by any other method of cleansing a substrate.

The substrate may be placed in the sample chamber 154 by way of a top or side-mounted door, whether manually by a human operator or by a robotic arm. Such a robotic arm may be directed by the controller 160.

The sample chamber may be configured to secure the substrate for cleansing through the use of a vacuum chuck.

The system may be configured to return the gas-enriched chemical mixture 102 to the mixing tank 126 after it has been dispensed in the sample chamber 154, as part of the dispense subsystem 150. The dispense subsystem 150 may include a return filter 156, which may include a membrane configured to filter debris or sediment from the gas-enriched chemical mixture 102 that may have been introduced within the sample chamber 154.

The dispense subsystem 150 may also comprise a return pump 158 configured to pump the spent gas-enriched chemical mixture from the sample chamber 154 to the mixing tank 126. The return filter 156, return pump 158, and the connections between these components, the sample chamber 154, and the mixing tank 126 may be referred to in some embodiments as a mixture reclaim line.

The system configuration 200 of FIG. 2 may also comprise a controller 160. In some embodiments, the controller 160 may include a processor 162 and a computer-readable medium 164 as illustrated in FIG. 1.

The controller 160 may execute, by the processor 162, instructions stored on the computer-readable medium 164 in response to communications from components of the system configuration 200 that have been operably connected to the controller.

For example, the controller 160 may adjust the operation of the MFC 111 and/or the gas generator 113 in response to the measured gas concentration received from the gas sensor 140. Should the temperature of the gas-enriched chemical mixture 102 go outside a specified range, the controller may in response adjust the operation of the temperature control unit 136 to change the temperature of the mixture until it is in the proper range.

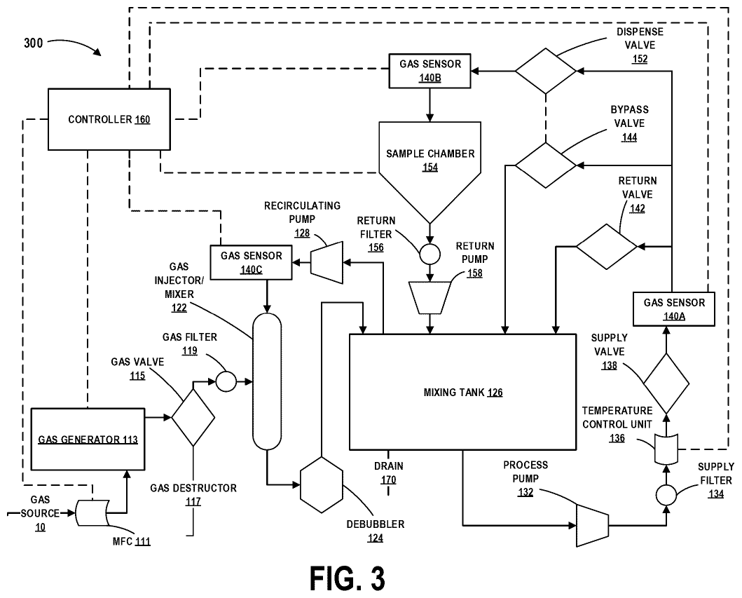

FIG. 3 depicts an example configuration 300 of the gas-injected chemistry system 100. Connections between elements with a solid line represent pipes or tubes configured for the transport of fluids such as gases and/or liquids. The arrow on such a connection represents the intended direction of the fluid flow. Connections between elements with a dashed line represent an operable connection, such as an electrical, optical, or mechanical connection.

Configuration 300 of the gas-injected chemistry system 100 operates similarly to configuration 200 depicted in FIG. 2, though it depicts several alternative locations for the gas sensor 140, depicted in FIG. 3 as gas sensors 140A, 140B, and 140C. In some embodiments, the configuration may use all, none, or any combination of the different gas sensors.

For example, gas sensor 140C may be used to determine the concentration of gas within the mixture being recirculated through the recirculating pump 128 to the gas injector/mixer 122. This information may be transmitted to the controller 160, which may adjust the operating parameters of the MFC 111 and/or the gas generator 113, which may change the gas concentration within the gas-enriched chemical mixture 102. An advantage of measuring the gas concentration at this point rather than at gas sensor 140A would be for more responsive changes to the gas-enriched chemical mixture 102 before it is provided to the mixture supply line for use in the sample chamber 154.

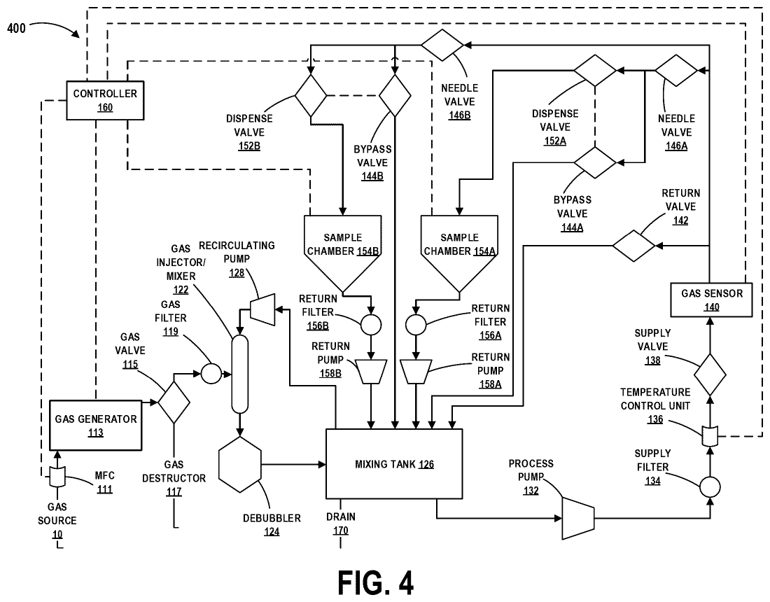

FIG. 4 depicts an example configuration 400 of the gas-injected chemistry system 100. Connections between elements with a solid line represent pipes or tubes configured for the transport of fluids such as gases and/or liquids. The arrow on such a connection represents the intended direction of the fluid flow. Connections between elements with a dashed line represent an operable connection, such as an electrical, optical, or mechanical connection.

Configuration 400 of the gas-injected chemistry system 100 operates similarly to configuration 200 depicted in FIG. 2, though it depicts multiple instances of the sample chamber 154, depicted in FIG. 4 as sample chambers 154A and 154B, along with their respective return filters 156A and 156B and return pumps 158A and 158B. In a multi-chamber configuration, each sample chamber 154 may be supplied by a needle valve 146, which controls the flow of the gas-enriched chemical mixture 102 to the dispense valve 152 and bypass valve 144 associated with each sample chamber 154. Accordingly, FIG. 4 depicts needle valve 146A supplying dispense valve 152A and bypass valve 144A, the former of which supplies sample chamber 154A. Another sample chamber may be configured in a similar way: FIG. 4 depicts needle valve 146B supplying dispense valve 152B and bypass valve 144A, the former of which supplies sample chamber 154B. Two sample chambers are depicted by way of example, though in some embodiments more sample chambers may be included depending on the needs of the system and the capacity constraints of other components, such as the gas supply subsystem 110 and mixture supply subsystem 130.

Each sample chamber may be configured to dispense the predetermined amount of gas-enriched chemical mixture 102 onto a substrate by spraying, by immersing the substrate in a bath of the gas-enriched chemical mixture 102, or by any other method of cleansing a substrate.

In some embodiments, each sample chamber may be configured to use a different method of dispensing the gas-enriched chemical mixture onto the substrate.

The systems described above, in differing configurations, may operate according to certain parameters to ensure proper and efficient functioning. The controller 160 may adjust such parameters to place the system in one of several modes of operation.

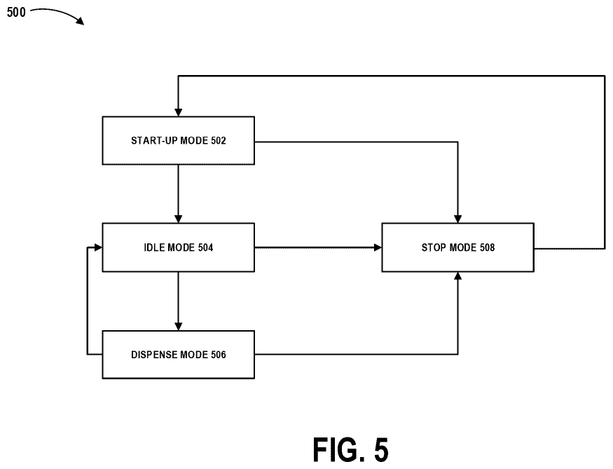

In some embodiments, the system may operate in one of four different modes: start-up, idle, dispense, and stop. The relationship between each of the four modes is illustrated in FIG. 5 with mode chart 500.

The start-up mode 502 may represent a state of the gas-injected chemistry system 100 in which the mixing tank 126 is empty (i.e. contains no gas-enriched chemical mixture 102) and such a mixture may be prepared. In this mode, the controller 160 may adjust the operation of the MFC 111 and the gas generator 113 to “ramp up” the production of a gas such that the desired concentration of the gas within the prepared gas-enriched chemical mixture 102 may be achieved as quickly as possible or at a predetermined rate. The start-up mode 502 may transition to idle mode 504 or stop mode 508.

The idle mode 504 may represent state of the gas-injected chemistry system 100 in which the mixing tank 126 contains a gas-enriched chemical mixture 102 which has the desired properties (e.g. concentration of gas and/or chemical makeup). Thus, the gas-enriched chemical mixture 102 is ready to be dispensed. In this mode, the gas-enriched chemical mixture 102 may circulate throughout the mixture dispense subsystem, but not to the sample chamber 154, as the dispense valve 152 may be closed and the bypass valve 144 may be open.

In the idle mode 504, the controller 160 may, in response to communications from a gas sensor 140, adjust the operation of the MFC 111, the gas generator 113, and/or temperature control unit 136 to maintain a constant gas concentration and mixture temperature according to desired operational parameters. The controller 160 may also adjust such operations to counteract gas decomposition within the gas-injected chemical mixture and/or the loss of gas during the circulation of the mixture. The idle mode 504 may transition to dispense mode 506 or stop mode 508.

The dispense mode 506 may represent a state of the gas-injected chemistry system 100 in which the gas-enriched chemical mixture 102 is dispensed onto a substrate within the sample chamber 154. In this mode, the bypass valve 144 and return valve 142 may be closed, while the dispense valve 152 may be open, allowing flow of the gas-enriched chemical mixture 102 to the sample chamber 154.

In the dispense mode 506, the controller 160 may, in response to communications from a gas sensor 140, adjust the operation of the MFC 111, the gas generator 113, and/or temperature control unit 136 to maintain a constant gas concentration and mixture temperature according to desired operational parameters. In particular, the controller 160 may adjust such operations to counteract the flow of the gas-poor liquid being returned to the mixing tank 126 from the sample chamber 154. The dispense mode 506 may transition to idle mode 504 or stop mode 508.

As described above, any other mode may transition to the stop mode 508. The stop mode 508 may represent a state of the gas-injected chemistry system 100 in which the gas-enriched chemical mixture 102 is drained from the system. This may occur as a course of normal operations, such as a predetermined change in gas-enriched chemical mixtures, or due to an error. In this mode, the return valve 142 and bypass valve 144 may both be opened in order to return any remaining mixture within the mixture supply subsystem 130 to the mixing tank 126. The mixing tank 126 may be drained via the drain 170.

In the stop mode 508, the controller 160 may adjust the operation of the MFC 111, the gas generator 113, and/or temperature control unit 136 to accelerate gas decomposition within the gas-enriched chemical mixture 102 and/or quicken the draining of the mixing tank 126 via the drain 170. The stop mode 508 may transition to start-up mode 502.

### III. Example Methods

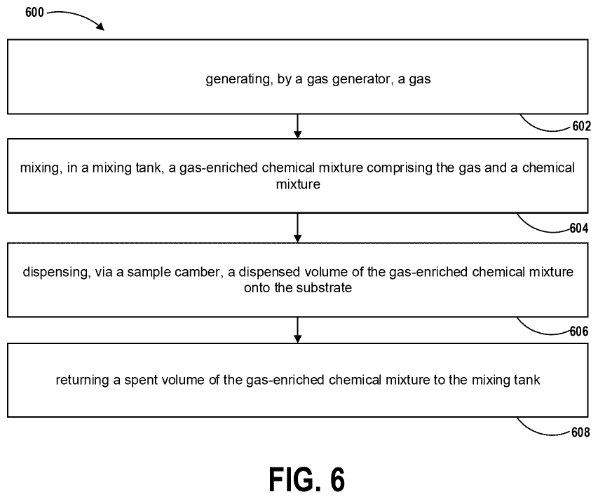

FIG. 6 illustrates a method 600, according to an example embodiment. Method 600 may include one or more steps or blocks, which may be carried out in any order. Furthermore, steps or blocks may be added or removed within the scope of the present disclosure. The steps or blocks of method 600 may be carried out once, continuously, periodically, or over discrete amounts of time.

FIG. 6 illustrates an example method 600 for cleaning a substrate, which may be carried out in association with, or by utilizing, some or all elements of a gas-injected chemistry system or configuration thereof as illustrated in and described in reference to FIGS. 1-4.

Block 602 may involve generating, by a gas generator (e.g., gas generator 113), a gas. The generating step may involve obtaining, from a gas source, a preliminary gas. The generating step may also involve providing, via a mass flow controller (MFC) (e.g., MFC 111) operably connected to a controller (e.g., controller 160), the preliminary gas to the gas generator. The generating step may also involve producing, by the gas generator, the gas from the preliminary gas.

Block 604 may involve mixing, in a mixing tank (e.g., mixing tank 126), a gas-enriched chemical mixture (e.g., gas-enriched chemical mixture 102) comprising the gas and a chemical mixture. The mixing step may involve pumping, via a recirculating pump (e.g., recirculating pump 128), a volume of the chemical mixture from the mixing tank to a gas injector (e.g., gas injector/mixer 122) connected to the mixing tank. The mixing step may involve injecting, via the gas injector, the gas into the chemical mixture. The mixing step may involve debubbling the gas-enriched chemical mixture. The mixing step may involve pumping the gas-enriched chemical mixture to the mixing tank.

In some embodiments, the gas-enriched chemical mixture may comprise an infused gas portion and a liquid portion. In some embodiments, the infused gas portion may comprise ozone (O₃). In some embodiments, the liquid portion may comprise hydrofluoric acid (HF).

Block 606 may involve dispensing, via a sample chamber (e.g., sample chamber 154), a dispensed volume of the gas-enriched chemical mixture onto the substrate. The dispensing step may involve pumping, via a process pump (e.g., process pump 132), the gas-enriched chemical mixture via a mixture dispense line to the sample chamber. The mixture dispense line may comprise a supply valve (e.g., supply valve 138), a return valve (e.g., return valve 142), a bypass valve (e.g., bypass valve 144), and a dispense valve (e.g., dispense valve 152). The bypass valve and dispense valve may be operably connected.

Block 608 may involve returning a spent volume of the gas-enriched chemical mixture to the mixing tank. The returning step may involve pumping, via a return pump (e.g., return pump 158), the spent volume of the gas-enriched chemical mixture to the mixing tank after interaction with the substrate.

### IV. Conclusion

The present disclosure is not to be limited in terms of the particular embodiments described in this application, which are intended as illustrations of various aspects. Many modifications and variations can be made without departing from its scope, as will be apparent to those skilled in the art. Functionally equivalent methods and apparatuses within the scope of the disclosure, in addition to those described herein, will be apparent to those skilled in the art from the foregoing descriptions. Such modifications and variations are intended to fall within the scope of the appended claims.

The above detailed description describes various features and operations of the disclosed systems, devices, and methods with reference to the accompanying figures. The example embodiments described herein and in the figures are not meant to be limiting. Other embodiments can be utilized, and other changes can be made, without departing from the scope of the subject matter presented herein. It will be readily understood that the aspects of the present disclosure, as generally described herein, and illustrated in the figures, can be arranged, substituted, combined, separated, and designed in a wide variety of different configurations.

With respect to any or all of the message flow diagrams, scenarios, and flow charts in the figures and as discussed herein, each step, block, operation, and/or communication can represent a processing of information and/or a transmission of information in accordance with example embodiments. Alternative embodiments are included within the scope of these example embodiments. In these alternative embodiments, for example, operations described as steps, blocks, transmissions, communications, requests, responses, and/or messages can be executed out of order from that shown or discussed, including substantially concurrently or in reverse order, depending on the functionality involved. Further, more or fewer blocks and/or operations can be used with any of the message flow diagrams, scenarios, and flow charts discussed herein, and these message flow diagrams, scenarios, and flow charts can be combined with one another, in part or in whole.

A step, block, or operation that represents a processing of information can correspond to circuitry that can be configured to perform the specific logical functions of a herein-described method or technique. Alternatively or additionally, a step or block that represents a processing of information can correspond to a module, a segment, or a portion of program code (including related data). The program code can include one or more instructions executable by a processor for implementing specific logical operations or actions in the method or technique. The program code and/or related data can be stored on any type of computer-readable medium such as a storage device including RAM, a disk drive, a solid state drive, or another storage medium.

The computer-readable medium can also include non-transitory computer-readable media such as computer-readable media that store data for short periods of time like register memory and processor cache. The computer-readable media can further include non-transitory computer-readable media that store program code and/or data for longer periods of time. Thus, the computer-readable media may include secondary or persistent long term storage, like ROM, optical or magnetic disks, solid state drives, compact-disc read only memory (CD-ROM), for example. The computer-readable media can also be any other volatile or non-volatile storage systems. A computer-readable medium can be considered a computer-readable storage medium, for example, or a tangible storage device.

Moreover, a step, block, or operation that represents one or more information transmissions can correspond to information transmissions between software and/or hardware modules in the same physical device. However, other information transmissions can be between software modules and/or hardware modules in different physical devices.

The particular arrangements shown in the figures should not be viewed as limiting. It should be understood that other embodiments can include more or less of each element shown in a given figure. Further, some of the illustrated elements can be combined or omitted. Yet further, an example embodiment can include elements that are not illustrated in the figures.

While various aspects and embodiments have been disclosed herein, other aspects and embodiments will be apparent to those skilled in the art. The various aspects and embodiments disclosed herein are for purpose of illustration and are not intended to be limiting, with the true scope being indicated by the following claims.

What is claimed:

1. A system comprising:
a gas generator configured to generate a gas;
a mixing tank configured to contain a gas-enriched chemical mixture, wherein the mixing tank is connected to the gas generator via a gas supply line;
a sample chamber configured to contain a substrate, wherein the sample chamber is connected to the mixing tank via a mixture dispense line, wherein the mixture dispense line is configured to supply a dispensed volume of gas-enriched chemical mixture to the sample chamber, wherein the sample chamber is connected to the mixing tank via a mixture reclaim line, wherein the mixture reclaim line is configured to return a spent volume of the gas-enriched chemical mixture to the mixing tank after interaction with the substrate;
a gas sensor; and
a controller, operably connected to the gas generator, the gas sensor, and the sample chamber, wherein the controller is configured to carry out program instructions stored in a memory so as to perform operations, the operations comprising:
receiving, from the gas sensor, information indicative of a concentration of the gas within the gas-enriched chemical mixture; and
in response to receiving the information, controllably adjusting at least one operational aspect of the system so as to obtain a desired concentration of gas within the gas-enriched chemical mixture.

2. The system of claim 1, wherein the sample chamber is configured to dispense the dispensed volume of gas-enriched chemical mixture onto the substrate.

3. The system of claim 1, wherein the gas-enriched chemical mixture comprises an infused gas portion and a liquid portion, wherein the infused gas portion comprises ozone (O₃), and wherein the liquid portion comprises hydrofluoric acid (HF).

4. The system of claim 1, wherein the operations further comprise:
in response to receiving a dispense command, controllably adjusting at least one operational aspect of the gas generator; and
subsequently dispensing a dispensed volume of the gas-enriched chemical mixture to the sample chamber.

5. The system of claim 1, wherein the gas generator is connected to a mass flow controller (MFC) configured to supply gas from a gas source to the gas generator, and wherein the MFC is operably connected to the controller.

6. The system of claim 1, wherein the mixture dispense line is further connected to the mixing tank via a return valve.

7. The system of claim 1, wherein the mixture dispense line is connected to the sample chamber via a dispense valve.

8. The system of claim 7, wherein the mixture dispense line is further connected to the mixing tank via a bypass valve, and wherein the dispense valve is operably connected to the bypass valve.

9. The system of claim 1, wherein the mixture reclaim line comprises a return pump configured to pump the spent volume of the gas-enriched chemical mixture to the mixing tank after interaction with the substrate.

10. The system of claim 1, wherein the gas is injected into the gas-enriched chemical mixture via a gas injector connected to the mixing tank.

11. The system of claim 10, wherein the mixing tank is connected to the gas injector via an injection line, and wherein the injection line is configured to supply the gas-enriched chemical mixture to the mixing tank.

12. The system of claim 11, wherein the injection line comprises:
a recirculating pump configured to pump a volume of the gas-enriched chemical mixture from the mixing tank to the gas injector; and
a debubbler configured to remove gas bubbles from the gas-enriched chemical mixture.

13. A method for cleaning a substrate comprising:
generating, by a gas generator, a gas;
mixing, in a mixing tank, a gas-enriched chemical mixture comprising the gas and a chemical mixture;
dispensing, via a sample chamber, a dispensed volume of the gas-enriched chemical mixture onto the substrate; and
returning a spent volume of the gas-enriched chemical mixture to the mixing tank.

14. The method of claim 13, wherein the gas-enriched chemical mixture comprises an infused gas portion and a liquid portion, wherein the infused gas portion comprises ozone (O₃), and wherein the liquid portion comprises hydrofluoric acid (HF).

15. The method of claim 13, wherein generating, by a gas generator, a gas comprises:
obtaining, from a gas source, a preliminary gas;
providing, via a mass flow controller (MFC) operably connected to a controller, the preliminary gas to the gas generator; and
producing, by the gas generator, the gas from the preliminary gas.

16. The method of claim 13, wherein mixing a gas-enriched chemical mixture comprising the gas and a chemical mixture comprises:
pumping, via a recirculating pump, a volume of the chemical mixture from the mixing tank to a gas injector connected to the mixing tank.
injecting, via the gas injector, the gas into the chemical mixture;
debubbling the gas-enriched chemical mixture; and
pumping the gas-enriched chemical mixture to a mixing tank.

17. The method of claim 13, dispensing, via a sample chamber, a dispensed volume of the gas-enriched chemical mixture onto the substrate comprises pumping, via a process pump, the gas-enriched chemical mixture via a mixture dispense line to the sample chamber, wherein the mixture dispense line comprises a supply valve, a return valve, a bypass valve, and a dispense valve, and wherein the bypass valve and dispense valve are operably connected.

18. The method of claim 13, wherein returning a spent volume of the gas-enriched chemical mixture to the mixing tank comprises pumping, via a return pump, the spent volume of the gas-enriched chemical mixture to the mixing tank after interaction with the substrate.

19. A non-transitory computer-readable medium comprising program instructions, that when executed by a processor cause a controller to perform operations comprising:
receiving, from a gas sensor, information indicative of a concentration of a gas within a gas-enriched chemical mixture; and
in response to receiving the information, controllably adjusting at least one operational aspect of a gas generator so as to obtain a desired concentration of gas within the gas-enriched chemical mixture.

20. The non-transitory computer-readable medium of claim 19, wherein the operations further comprise:
in response to receiving a dispense command, controllably adjusting at least one operational aspect of the gas generator; and
subsequently dispensing a dispensed volume of the gas-enriched chemical mixture to a cleansing sample chamber.
